(19) United States
(12) Patent Application Publication
(10) Pub. No.: US 2010/0002395 A1
(43) Pub. Date: Jan. 7, 2010

(54) ELECTRONIC HOUSING WITH ELECTRONIC BOARDS COMPRISING HEAT PIPES

(75) Inventors: Pierre Bertrou, Merignac (FR); Catherine Lavergne, Talence (FR); Stephane Poveda, Merignac (FR)

Correspondence Address: LOWE HAUPTMAN HAM & BERNER, LLP, 1700 DIAGONAL ROAD, SUITE 300, ALEXANDRIA, VA, 22314, US

(73) Assignee: THALES, Neuilly Sir Seine (FR)

(21) Appl. No.: 12/446,640

(22) PCT Filed: Oct. 17, 2007
(86) PCT No.: PCT/EP2007/061101

§ 371 Date: Apr. 22, 2009

(30) Foreign Application Priority Data
Oct. 24, 2006 (FR) 0609300

(51) Int. Cl. H05K 7/20

(52) U.S. Cl. 361/700; 361/688

(57) ABSTRACT

The field of the invention is that of the discharge of heat from electronic cards in operation and more specifically from electronic devices comprising at least one heat pipe. The electronic package according to the invention comprises at least a mechanical structure comprising at least one housing, an electronic card, and means for mechanically attaching the electronic card in the housing of the structure, the electronic card comprising at least one electronic component and a device of high thermal conductivity joined to the electronic card and comprising two ends, the first end being in thermal contact with the electronic component and the second end of the device of high thermal conductivity being mechanically arranged so as to ensure good thermal contact with the walls of the housing of the structure.

### CROSS-REFERENCE TO RELATED APPLICATIONS

The present Application is based on International Application No. PCT/EP2007/061101, filed on Oct. 17, 2007, which in turn corresponds to French Application No. 06 09300, filed on Oct. 24, 2006 and priority is hereby claimed under 35 USC §119 based on these applications. Each of these applications are hereby incorporated by reference in their entirety into the present application.

### BACKGROUND OF THE INVENTION

1. Filed of the Invention

The field of the invention is that of the discharge of heat from electronic cards in operation and more specifically from electronic devices comprising at least one heat pipe.

2. Description of the Invention

The components of electronic cards dissipate a large amount of heat, causing a significant increase in the temperature of associated components and electronic circuits. This rise in temperature may reach several tens of degrees. It is all the larger as for some professional applications the electronic cards are situated in an environment already at a raised temperature. This is the case for some aeronautical or defense applications. However, the characteristics, the reliability and the lifetime of a large number of electronic components depend greatly on the temperature. It is therefore vital for the security of operation of an electronic device that the heat is controlled and discharged in proper conditions.

It is known that heat transfer can be produced by:
thermal radiation. A hot body naturally emits thermal radiation. This emission is not enough to allow effective discharge of the heat.
thermal convection. When the hot body is in contact with moving gas or liquid fluids, part of the thermal energy is transferred to the fluid. For the convection to be effective, it is preferable that the circulation of the fluid is forced so as to optimize the heat exchange. Consequently, means for pumping and discharging the fluid are necessary. For example, when the fluid is a gas, forced ventilation is brought about by means of fans.
thermal conduction: this takes place between two bodies at different temperatures connected to one another by a solid, liquid or gas substance in which the thermal energy is propagated due to inelastic impacts between molecules.

The discharge of heat by thermal conduction is preferred when, due to problems of weight, bulk, sealing and cost, the possibility does not exist of using thermal convection which necessitates particular means of heat extraction and discharge. This is the mode of discharge adopted for a certain number of electronic computers and notably computers on board aircraft.

In order to discharge heat, it is possible to use heat pipes. A heat pipe is a closed system that makes it possible, by benefitting from phase changes of a coolant, to remove heat from one location and to redistribute it at another. Its operation is shown diagrammatically in FIG. 1. A liquid is enclosed in a tube 10 comprised of three parts: the evaporator 11 which ensures the removal of heat, the condenser 12 which ensures its redistribution, and the adiabatic zone 13 which ensures the heat transfer from the evaporator 11 to the condenser 12. The amount of liquid introduced is such that the liquid is in equilibrium with its vapor phase so that moderate thermal variations ensure the liquid-vapor change of state. At the evaporator 11 the liquid will take on its gas form and go towards the condenser 12 where it will reliquify. It will then be returned to the evaporator using a wick 14 contained in the adiabatic zone. In FIG. 1 the white arrows indicate the circulation of the coolant when it is in liquid form and the gray arrows indicate the circulation of the coolant when it is in gas form. Thanks to the wick 14, the heat pipe 10 is able to operate in all positions. The thermal conductivity of the heat pipe is ensured by the moving gas and is much higher than that of heat conducting materials, such as copper for example. There are various forms of heat pipes which may be produced in the form of tubes, plates, layers, etc.

There are various possibilities for fitting heat pipes to an electronic package. They are illustrated in FIGS. 2, 3 and 4. In these figures the following conventions have been adopted in the interest of clarity:
the electronic component 1 to be cooled is represented by a black rectangle;
the electronic card 2 which bears this component 1 is represented by a rectangle comprising a first dotted pattern;
the electronic package 3 which bears the electronic card 2 is represented by an outline with two lines;
the parts 4 that ensure the thermal junction between the heat pipe 10 and the other parts comprise a second dotted pattern.

In a first embodiment illustrated in FIG. 2, the evaporator part of the heat pipe 10 is positioned on the electronic component 1 to be cooled. In general, the attachment of the heat pipe 10 on the component 1 is ensured by means of a transfer part 4 in which the evaporator part of the heat pipe 10 is attached. This transfer part 4 is attached on the component by means of a heat-conducting thermal grease. The shape of the transfer part is adapted to the size of the component to ensure optimal heat transfer. The condenser part of the heat pipe 10 is connected to a fan 5, symbolized by a crossed-through rectangle in FIG. 2. This fan 5 is located at the rear of the electronic package. The main drawback of this solution is that it requires a fan, which necessarily causes package production, weight, size and sealing problems and production cost problems.

In a second embodiment illustrated in FIG. 3, which shows a front view and a side view of an electronic package, the condenser part of the heat pipe 10 is connected to a drain 6 or to a heat sink by means of an adapter part 4. In this case, the fan is no longer necessary, but the dissipative system discharges the heat into higher surroundings. Consequently, in order to ensure a certain effectiveness, the drain 6 necessarily has a large surface area. To avoid too large a size requirement, it is possible to mount the drain as a mezzanine above the card by means, as can be seen in FIG. 3, of posts 7. However, the size requirement remains substantial and of course the dissipation is limited to simple convection from the drain or from the heat sink.

In a third embodiment, illustrated in FIG. 4, the condenser part of the heat pipe 10 is connected to the electronic package 3 by means of an adapter part 8. This latter solution has the advantages of requiring neither a fan nor a heat sink. On the other hand, the electronic package is generally made of a material that conducts heat well and has a large dissipation area. However, this mounting is necessarily complex insofar as the adapter part must be positioned and attached on the package, which facilitates neither the mounting operations nor the operations of dismounting the electronic card 2. Conversely, insofar as the heat pipe 10 is bound to both the electronic card 2 and the package 3, this mounting is more sensitive to vibrating environments such as may be found when the electronic package is located in an aircraft.

### SUMMARY OF THE INVENTION

The device according to the invention make it possible to eliminate the various drawbacks of these embodiments.

More precisely, the subject of the invention is an electronic package comprising at least:
a mechanical structure comprising at least one housing,
an electronic card, and
means for mechanically attaching the electronic card in the housing of said structure,
the electronic card comprising at least one electronic component and a device of high thermal conductivity comprising two ends, the first end being in thermal contact with said electronic component, characterized in that the second end of the device of high thermal conductivity is mechanically arranged so as to ensure good thermal contact with the walls of the housing of the structure.

Advantageously, the electronic card comprises an interface part situated between the walls of the housing and the second end of the device of high thermal conductivity.

Advantageously, the housing of the structure has the form of a straight groove with a U-shaped cross section.

Advantageously, the means for mechanically attaching the electronic card are wedge retainer devices, also known as card-lock retainers or wedge-lock retainers.

Advantageously, the device of high thermal conductivity is a heat pipe comprising an evaporator part and a condenser part, the first end corresponding to the evaporator part and the second end corresponding to the condenser part of said heat pipe.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 shows the working principle of a heat pipe;

FIGS. 2, 3 and 4 show three different modes of fitting heat pipes to electronic cards according to the prior art;

FIG. 5 shows a sectional view of an electronic package comprising a heat-pipe fitting according to the invention; and

FIG. 6 shows the principle for mounting devices for retaining electronic cards comprising wedges.

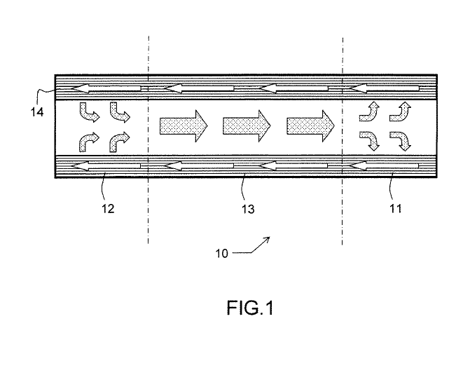

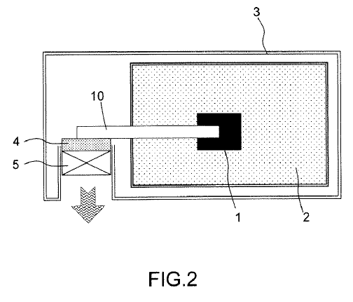

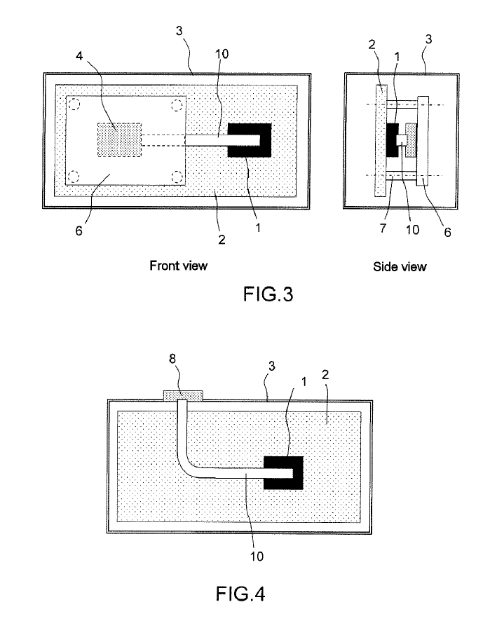

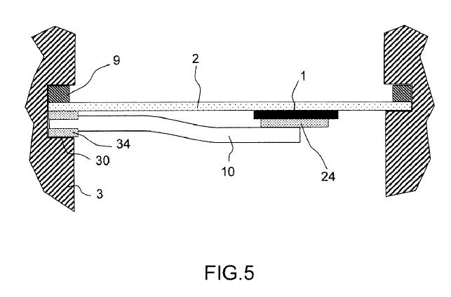

### DETAILED DESCRIPTION OF THE INVENTION

The invention is based on the two following observations:
the device of high thermal conductivity that enables the discharge of the heat dissipated by the electronic component(s) of the card must be joined to this so as to permit straightforward mounting and dismounting;
this device must be connected to the electronic package so as to enable effective discharge of the heat.

To meet these constraints, the devices of high thermal conductivity according to the invention are on the one hand joined to the electronic card and on the other hand are positioned such that one of their ends is situated in the housing of the structure ensuring that the electronic card is retained in its package.

By way of nonlimiting example, FIG. 5 shows a sectional view of an electronic package comprising a fitting of the device of high thermal conductivity according to the invention. In FIG. 5 only the parts of the package comprising the housing for the electronic card are shown.

In the case of FIG. 5, the device of high thermal conductivity is a heat pipe 10. Of course, other devices of high conductivity might be fitted.

The electronic card 2 comprises at least one hot component 1 which is intended to be cooled.

The evaporator part of the heat pipe 10 is positioned on this electronic component 1. Optionally, to ensure better thermal conduction, the attachment of the heat pipe to the component may be ensured by means of a transfer part 24 in which the evaporator part of the heat pipe 10 is attached. This transfer part 24 is attached to the component by means of a heat-conducting thermal grease.

The electronic package 3 comprises a mechanical structure that is generally a good conductor of heat. This mechanical structure comprises at least one housing 30 in which the electronic card 2 is housed. Mechanical attachment means 9 ensure that the electronic card 2 is retained in its housing 30.

The condenser part of the heat pipe 10 is positioned so as to ensure good thermal contact with the walls of the housing 30 of the structure. Here again, as can be seen in FIG. 5, an interface part 34 situated between the walls of the housing 30 and the second end of the heat pipe 10 make it possible to improve thermal conductivity.

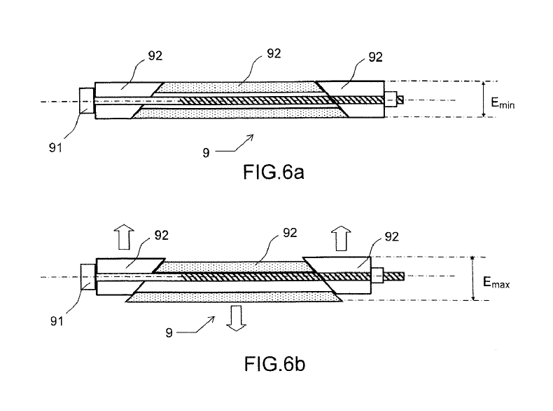

Generally, the electronic cards are slid into housings in the form of a straight groove with a U-shaped cross section. In this case the means of mechanical attachment may be wedge retainer devices, better known under the brand “card-ok retainers” marketed by the company Calmark, or “wedge-lock retainers” marketed by the company Birtcher. The working principle of these wedge devices is shown in FIGS. 6a and 6b. Each wedge 9 essentially comprises several wedges 92 of trapezoidal shape arranged head-to-foot so as to form a single wedge with the shape of an elongate parallelepiped and a central screw 91 that passes through the assembly of wedges 92 so as to hold them together. Operation is simple. When the screw 91 is not tightened, the assembly of wedges 92 has a thickness Eₘᵢₙ, as shown in FIG. 6a. When the screw 91 is tightened, the wedges 92 separate and the assembly of wedges has an apparent thickness Eₘₐₓ, as shown in FIG. 6b, Eₘᵢₙ being less than Eₘₐₓ. Thus, when one of these wedges 9 is slid into the housing of the structure, between the heat pipe 10 of the electronic card 2 and the walls of the housing 30, by tightening the screw 91 the electronic card and the heat pipe are pressed up against the walls of the housing.

When the heat pipe is in the form of a tube, it is possible to bend the tube so that the bent part matches the groove. In this way, the heat exchange surface area between the heat pipe and the electronic package is increased.

It should also be noted that this fitting of the heat pipe makes it possible to leave free the largest fitting surface for electronic components on the card.

Finally, in this arrangement the heat pipe also serves as a mechanical stiffener of the electronic card.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. An electronic package comprising:
a mechanical structure having a housing,
an electronic card, and
means for mechanically attaching the electronic card in the housing of said structure,
the electronic card having an electronic component and a device of high thermal conductivity joined to the electronic card and having two ends, both joined to the electronic card, the first end being in thermal contact with said electronic component, wherein the second end of the device of high thermal conductivity is mechanically arranged so as to ensure good thermal contact with the walls of the housing of the structure.

2. The electronic package as claimed in claim 1, wherein the electronic card comprises an interface part situated between the walls of the housing and the second end of the device of high thermal conductivity.

3. The electronic package as claimed in claim 1, wherein the housing of the structure has the form of a straight groove with a U-shaped cross section.

4. The electronic package as claimed in claim 1, wherein the means for mechanically attaching the electronic card are wedge retainer devices, also known as card-lock retainers or wedge-lock retainers, each wedge essentially comprising several wedges of trapezoidal shape arranged head-to-foot so as to form a single wedge with the shape of an elongate parallelepiped and a central screw that passes through the assembly of wedges so as to hold them together.

5. The electronic package as claimed in claim 1, wherein the device of high thermal conductivity is a heat pipe comprising an evaporator part and a condenser part, the first end corresponding to the evaporator part and the second end corresponding to the condenser part of said heat pipe.
